(19) United States
(12) Patent Application Publication
(10) Pub. No.: US 2026/0005058 A1
(43) Pub. Date: Jan. 1, 2026

(54) DIRECT VOLTAGE CONTROL OF A CLAMPING SURFACE OF AN ELECTROSTATIC CLAMP

(71) Applicant: Axcelis Technologies, Inc., Beverly, MA (US)

(72) Inventors: Robert T. Fryer, Nottingham, NH (US); Kevin W. Wenzel, Belmont, MA (US)

(21) Appl. No.: 19/251,973

(22) Filed: Jun. 27, 2025

Related U.S. Application Data
(60) Provisional application No. 63/664,744, filed on Jun. 27, 2024.

(51) Int. Cl. H01L 21/683; H01L 21/67

(52) U.S. Cl. CPC H01L 21/6833; H01L 21/67259

(57) ABSTRACT

A system and method for clamping a workpiece positions a workpiece on a clamping surface of an electrostatic clamp (ESC). The clamping surface is electrically grounded or electrically floated based on conditions of the workpiece and the ESC, such as a resistivity of the workpiece, where the clamping surface is electrically floated when the resistivity of the workpiece is high. A clamping voltage is applied to the ESC to clamp the workpiece to the clamping surface for semiconductor processing. The clamping surface is electrically coupled to an electrical ground for releasing the workpiece from the clamping surface. A release status of the workpiece is determined, to be in a clamped or released state. When the release status is clamped, a bias potential is applied to the clamping surface by a switch to promote de-clamping. When the release status is released, the workpiece is removed from the clamping surface.

### REFERENCE TO RELATED APPLICATIONS

This application claims the benefit of U.S. Provisional Application Ser. No. 63/664,744 filed Jun. 27, 2024, entitled, “DIRECT VOLTAGE CONTROL OF A CLAMPING SURFACE OF AN ELECTROSTATIC CLAMP”, the contents of all of which are herein incorporated by reference in their entirety.

### FIELD

The present invention relates generally to electrostatic clamping systems, and more specifically to system and method for quickly electrostatically clamping and releasing a workpiece having a high resistivity.

### BACKGROUND

Electrostatic clamps or chucks (ESCs) are often utilized in the semiconductor industry for clamping workpieces or substrates during plasma-based or vacuum-based semiconductor processes such as ion implantation, etching, chemical vapor deposition (CVD), etc. Clamping capabilities of the ESCs, as well as workpiece temperature control, have proven to be quite valuable in processing semiconductor substrates or wafers, such as silicon wafers. A typical ESC, for example, comprises a dielectric layer positioned over a conductive electrode, wherein the semiconductor wafer is placed on a surface of the ESC (e.g., the wafer is placed on a surface of the dielectric layer). During semiconductor processing (e.g., ion implantation), a clamping voltage is typically applied between the wafer and the electrode, wherein the wafer is clamped against the chuck surface by electrostatic forces.

### SUMMARY

The present disclosure details a workpiece support for clamping and de-clamping workpieces from an electrostatic clamp in a semiconductor processing system. Accordingly, the following presents a simplified summary of the disclosure in order to provide a basic understanding of some aspects of the invention. This summary is not an extensive overview of the invention. It is intended to neither identify key or critical elements of the invention nor delineate the scope of the invention. Its purpose is to present some concepts of the invention in a simplified form as a prelude to the more detailed description that is presented later.

In accordance with various examples of the present disclosure, an electrostatic clamping system is provided. The electrostatic clamping system comprises an electrostatic clamp having a clamping surface configured to contact a backside surface of a workpiece. One or more electrodes of the electrostatic clamp are positioned below the clamping surface, wherein a clamping voltage applied to the one or more electrodes is configured to electrostatically attract the workpiece to the clamping surface. An electrical contact of the electrostatic clamp is electrically coupled to the clamping surface. Further, a switch circuit is provided and configured to selectively electrically couple the clamping surface to each of an electrical ground, a bias power supply configured to finitely bias the clamping surface to a bias voltage, and an open position configured to electrically float the clamping surface, wherein the respective selective electrical coupling is based on one or more conditions.

The one or more conditions, for example, can comprise a physical property of the workpiece, such as one or more of a constituent material of the workpiece, a physical structure of the workpiece, and one or more layers defined on the workpiece, such as an electrically insulative or electrically conductive backside film.

A controller, for example, is further provided and configured to control the switch circuit based on the one or more conditions. For example, the switch circuit comprises a manual or automated electrical switch configured to selectively electrically couple an electrical ground contact of the electrostatic clamp to the electrical ground based on a signal from the controller.

The one or more conditions, for example, can comprise a state of sticking of the workpiece to the clamping surface after semiconductor processing has been performed on the workpiece. The controller can be configured to determine the state of sticking of the workpiece based on a monitoring of one or more of the clamping voltage and the bias voltage.

In accordance with another example of the present disclosure, a method is provided for clamping a workpiece, wherein the workpiece is positioned on a clamping surface of an electrostatic clamp. The clamping surface of the electrostatic clamp is electrically grounded or electrically floated based on one or more predetermined conditions associated with the workpiece and the electrostatic clamp. For example, the one or more predetermined conditions can comprise a resistivity of the workpiece, wherein the clamping surface is electrically floated when the resistivity of the workpiece is greater than a predetermined resistivity.

A set of clamping parameters, such as a clamping voltage, are applied to the electrostatic clamp, therein clamping the workpiece to the clamping surface of the electrostatic clamp. The workpiece then undergoes semiconductor processing, such as ion implantation, plasma processing, or other processing. The clamping surface is then selectively electrically coupled to an electrical ground for releasing the workpiece from the clamping surface.

A release status of the workpiece, for example, is then determined, wherein the release status comprises one of a clamped state or a released state, wherein the workpiece is substantially clamped to the clamping surface in the clamped state, and wherein the workpiece is substantially released or free from the clamping surface in the released state. When the release status of the workpiece is in the clamped state, the method comprises providing a bias potential to the clamping surface to aid in de-clamping the workpiece from the clamping surface. When the determination is such that the release status of the workpiece is in the released state, the workpiece can be safely removed from the clamping surface. For example, the present method provides for dissipating residual charge from the electrostatic clamp prior to removing the workpiece from the clamping surface.

### BRIEF DESCRIPTION OF THE DRAWINGS

FIG. 1 is a block diagram of an exemplary electrostatic clamping system in accordance with several aspects of the present disclosure.

FIG. 2 illustrates a flow methodology for minimizing a de-clamping time of a workpiece from an ESC, in accordance with still another aspect.

FIG. 3 is a block diagram illustrating an exemplary vacuum system utilizing an ESC in accordance with several aspects of the present disclosure.

### DETAILED DESCRIPTION

Electrostatic clamps or chucks (ESCs) are often utilized in the semiconductor industry for clamping workpieces or substrates during plasma-based or vacuum-based semiconductor processes such as ion implantation, etching, chemical vapor deposition (CVD), etc. Clamping capabilities of the ESCs, as well as workpiece temperature control, have proven to be quite valuable in processing semiconductor substrates or wafers, such as silicon wafers. An ESC, for example, comprises a dielectric layer positioned over a conductive electrode, wherein the semiconductor wafer is placed on a surface often referred to as a workpiece contacting surface (WCS) of the ESC. For example, the wafer is placed on a surface of the dielectric layer serving as the WCS. During semiconductor processing (e.g., ion implantation), a clamping voltage is typically applied between the wafer and the electrode, wherein the wafer is clamped against the surface of the ESC by electrostatic forces.

An electrostatic clamp can exhibit “sticking” behavior at one time or another, whereby a workpiece is retained against a surface of the ESC, despite the ESC no longer being powered. Sticking of a workpiece to the surface of an ESC is generally attributed in part to residual electrostatic charges at the interface between the ESC and workpiece not finding a rapid path to electrical ground after removal of power to the electrodes of the ESC. The nature, amount, and distribution of the residual charge is generally uncontrolled since the phenomena that retain the charge are also generally uncontrolled.

An electrostatic clamp used in ion implantation, for example, can implement charge-drain features that assist in electrically grounding the wafer and/or the WCS in order to prevent wafers from building charge or electrostatically “sticking” to the deactivated ESC. These features provide many benefits, such as reducing de-clamping times, particle contamination, wafer mishandling, and cases of extreme sticking where manual intervention or vacuum chamber venting is required to remove the wafer from the ESC.

One implementation of such charge-drain features involves a permanently grounded, electrically conductive surface coating serving as the WCS. However, there are cases, particularly the clamping of highly resistive, difficult-to-clamp workpieces, in which such a permanently grounded surface hinders the intended function of the ESC, as it naturally attenuates the clamping field, thereby lowering the achieved clamping force on the workpiece. For such applications, a permanently grounded WCS is omitted from the design of the ESC.

Thus, in accordance with various aspects of the present disclosure, a control over a WCS voltage potential to an ESC is provided, thus allowing direct control over three generic states. Namely, control is provided for an electrically grounded (closed) state, an electrically floated (open) state, and a tuned state that generally provides a finite voltage to the WCS. As such, the present disclosure provides numerous advantages over previously ineffective or incompatible applications. The present disclosure has utility in any application of semiconductor processing, such as ion implantation, plasma etching, and other applications that experience charging of a workpiece during clamping and/or processing.

In one example embodiment, the present disclosure provides one or more workpiece grounding features positioned between an ESC electrode plane and a workpiece plane. Such workpiece grounding features, for example, can have an effect of fundamentally lowering a clamping strength, as they attenuate the field strength by drawing charge from ground in order to balance the field inside intermediate conductors (e.g., a coating associated with a workpiece support surface). Accordingly, ESCs designed specifically for hard-to-clamp workpieces or substrates, such as a workpiece comprising highly resistive and insulating substrates (e.g., glass, silicon-on-insulator, MEMS), for example, generally omit such permanently grounded features, since a margin for achieving sufficient clamping force is typically too narrow.

The lack of free carriers, for example, can make such workpieces and substrates difficult to clamp, while concurrently making them prone to sticking issues and operating challenges without grounding features employed. As such, clamping and handling of resistive workpieces can pose challenges, and such workpieces are often plagued by extreme sticking that prevents or limits the process capabilities for such workpieces altogether. Thus, the present disclosure advantageously provides a switchable ground to the WCS, whereby the WCS can be selectively configured to be open circuit (floated) while clamping, for example, and grounded or finitely biased while de-clamping. As such, the present disclosure provides the beneficial features of grounding of the WCS only when such grounding is compatible with the workpiece, and wherein the grounding is advantageously synchronized with the sequence of clamping and unclamping.

In another example embodiment, in cases where conducting or semiconducting workpieces comprise an electrically resistive backside film, the present disclosure appreciates that while grounding the WCS can provide charge neutralization to the workpiece interface, the workpiece can still remain clamped or “stick” to the ESC after processing due to charge stored within the workpiece, itself. In such a case, the electric potential of the WCS can be advantageously tuned or controlled to match the potential of the workpiece, thereby exerting an electrostatically repulsive force on the workpiece to assist in its removal.

The present disclosure is thus directed generally toward a system, apparatus, and method for minimizing a charge build-up in workpieces and the associated de-clamping time for releasing the workpiece from an electrostatic clamp. Accordingly, the present invention will now be described with reference to the drawings, wherein like reference numerals may be used to refer to like elements throughout. It is to be understood that the description of these aspects are merely illustrative and that they should not be interpreted in a limiting sense. In the following description, for purposes of explanation, numerous specific details are set forth in order to provide a thorough understanding of the present invention. It will be evident to one skilled in the art, however, that the present invention may be practiced without these specific details. Further, the scope of the invention is not intended to be limited by the embodiments or examples described hereinafter with reference to the accompanying drawings, but is intended to be only limited by the appended claims and equivalents thereof.

It is also noted that the drawings are provided to give an illustration of some aspects of embodiments of the present disclosure and therefore are to be regarded as schematic only. In particular, the elements shown in the drawings are not necessarily to scale with each other, and the placement of various elements in the drawings is chosen to provide a clear understanding of the respective embodiment and is not to be construed as necessarily being a representation of the actual relative locations of the various components in implementations according to an embodiment of the invention. Furthermore, the features of the various embodiments and examples described herein may be combined with each other unless specifically noted otherwise.

It is also to be understood that in the following description, any direct connection or coupling between functional blocks, devices, components, circuit elements or other physical or functional units shown in the drawings or described herein could also be implemented by an indirect connection or coupling. Furthermore, it is to be appreciated that functional blocks or units shown in the drawings may be implemented as separate features or circuits in one embodiment, and may also or alternatively be fully or partially implemented in a common feature or circuit in another embodiment. For example, several functional blocks may be implemented as software running on a common processor, such as a signal processor. It is further to be understood that any connection which is described as being wire-based in the following specification may also be implemented as a wireless communication, unless noted to the contrary.

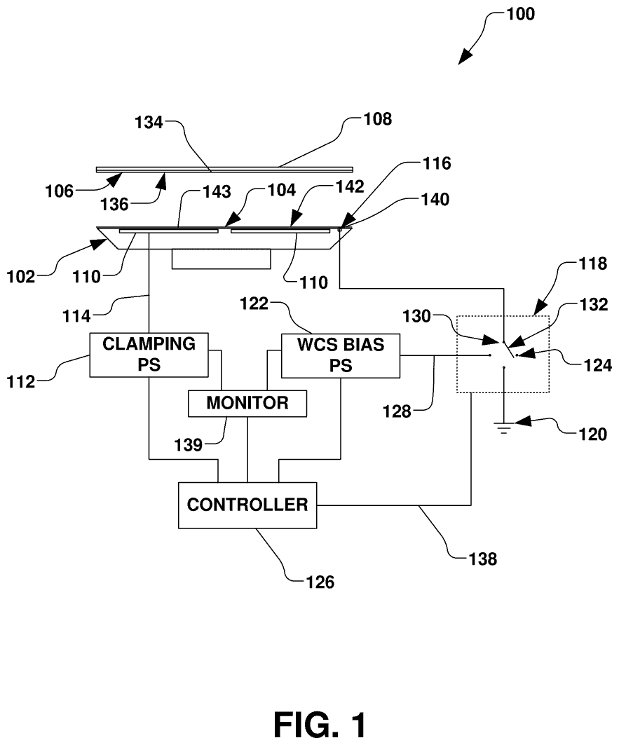

As illustrated in FIG. 1, an electrostatic clamping system 100 is shown, wherein the electrostatic clamping system comprises an electrostatic clamp 102. The electrostatic clamp 102, for example, comprises a clamping surface 104 configured to contact a backside surface 106 of a workpiece 108. The clamping surface 104, for example, may comprise one or more insulative or conductive layers. One or more electrodes 110 are positioned below the clamping surface 104, wherein a clamping power supply 112 is configured to selectively apply clamping parameters 114 (e.g., a clamping voltage) to the one or more electrodes 110 to electrostatically attract the workpiece 108 to the clamping surface 104. A WCS electrical contact 116 is further provided and electrically coupled to the clamping surface 104 of the electrostatic clamp 102.

In accordance with one example of the present disclosure, a switch circuit 118 (e.g., a three-way switch) is electrically coupled to the WCS electrical contact 116. The switch circuit 118, for example, is configured to selectively electrically couple the WCS electrical contact 116 to one of an electrical ground 120 or a WCS bias power supply 122. The switch circuit 118, for example, is further configured to electrically float the WCS electrical contact at a float position 124 (also called an open position), whereby the WCS electrical contact is electrically coupled to neither of the electrical ground 120 or the WCS bias power supply 122.

A controller 126, for example, is further provided and configured to control the switch circuit 118, whereby the selective electrical coupling of the WCS electrical contact 116 to the electrical ground 120 or the WCS bias power supply 122, or electrically floating the WCS electrical contact at the float position 124 is based on one or more conditions associated with the workpiece 108 and ESC 102. The one or more conditions, for example, can comprise one or more predetermined conditions such as a property or composition of the workpiece 108 and/or an understanding of historical or predetermined sticking behavior based on such a property of composition of the workpiece. The one or more conditions can further comprise one or more determined conditions, such as whether the workpiece 108 remains clamped or “sticks” to the clamping surface 104, as will be discussed in greater detail infra.

The controller 126, for example, is further configured to control one or more aspects of the electrostatic clamping system 100, such as a control of the clamping parameters 114 (e.g., the clamping voltage) supplied to the one or more electrodes 110 of the electrostatic clamp 102 by the clamping power supply 112. The controller 126, for example, can further control the WCS bias power supply 122 to control a WCS bias voltage 128 supplied to the WCS electrical contact 116. For example, the switch circuit 118 can comprise a switch 130, whereby the controller 126 is configured to control a position 132 of the switch to provide the selective electrical coupling of the WCS electrical contact 116 to the electrical ground 120, the WCS bias power supply 122, or the float position 124 based on the one or more conditions.

The one or more conditions, for example, can comprise a physical property of the workpiece 108. The physical property of the workpiece 108, for example, can comprise one or more of a constituent material of the workpiece, a physical structure of the workpiece, and one or more layers 134 defined on the workpiece. The constituent material of the workpiece 108, for example, can comprise one or more of silicon, glass, carbide, and nitride. In one example, the one or more layers 134 defined on the workpiece 108 comprise a backside film 136 that is disposed, formed, or otherwise residing on the workpiece and defining the backside surface 106.

In one example, the backside film 136 defining the backside surface 106 of the workpiece 108 is electrically insulative. In another example, the backside film 136 is electrically conductive. The physical structure of the workpiece 108, for example, can comprise one or more features (not shown) defined on the backside surface 106 of the workpiece.

The present disclosure contemplates the switch circuit 118 comprising any variety of electro-mechanical switches, relays, or various other logic or programmable switches configured to selectively electrically couple the WCS electrical contact 116 to the electrical ground 120, the WCS bias power supply 122, or the float position 124 to electrically float the WCS electrical contact. It is to be further appreciated that the controller 126 can comprise a single controller as shown in FIG. 1, or any number of controllers configured to selectively control the clamping power supply 112, the WCS bias power supply 122, and the switch circuit 118, and all such controllers are contemplated as falling within the scope of the present disclosure.

The switch circuit 118, for example, can comprise an automated electrical switch configured to provide the selective electrical coupling of the WCS electrical contact 116 of the electrostatic clamp 102 described above based on a signal 138 from the controller 126. The controller 126, for example, is further configured to send the signal 138 to the switch circuit 118 based on the one or more conditions. The one or more conditions, for example, can comprise a state of the workpiece 108 after semiconductor processing has been performed thereon, such as a state of sticking of the workpiece to the electrostatic clamp 102 after ion implantation. For example, the controller 126 can be configured to detect or determine the state of sticking of the workpiece 108 to the electrostatic clamp 102 based on monitoring of one or more of the clamping parameters 114 supplied to the one or more electrodes 110 by the clamping power supply 112 and the WCS bias voltage 128 supplied to the WCS electrical contact 116 by the WCS bias power supply 122. In one example, a monitor 139 can be configured to provide feedback (e.g., signals associated with one or more of a voltage, current, or capacitance) to the controller 126 from one or more of the clamping power supply 112 and the WCS bias power supply 122, wherein the feedback is associated with the state of sticking of the workpiece 108 to the clamping surface 104. The state of sticking of the workpiece 108 to the electrostatic clamp 102 can be based on a predetermined minimal clamping force that can be safely overcome during a removal of the workpiece from the electrostatic clamp without damaging the workpiece. Alternatively, the switch circuit 118 can comprise an electrical switch configured to selectively electrically couple the WCS electrical contact 116 of the electrostatic clamp 102 via a manual selection by a human operator.

In one example, the WCS electrical contact 116 simply provides an electrical coupling of the workpiece 108 to the clamping surface 104 of the ESC 102. In another example, the WCS electrical contact 116 comprises a ground pin 140 associated with the clamping surface 104 of the electrostatic clamp 102. The ground pin 140, for example, is configured to electrically contact the backside surface 106 of the workpiece 108 when the backside surface is in contact with the clamping surface 104 of the electrostatic clamp 102. In another example, the clamping surface 104 comprises a dielectric layer 142, such as a ceramic, and wherein the ground pin 140 is electrically coupled to the dielectric layer. The dielectric layer 142, for example, generally defines the clamping surface 104. The clamping surface 104, for example, can further comprise one or more surface layers 143 (e.g., one or more charge dissipation layers, conductive coatings, etc.) defined thereon or therein, wherein the one or more surface layers are configured to dissipate a charge associated with one or more of the clamping surface and the workpiece 108 based, at least in part, on the selective electrical coupling of the WCS electrical contact 116 via the switch circuit 118.

In another example, the WCS bias power supply 122, for example, is configured to selectively supply the WCS bias voltage 128 to the clamping surface 104, wherein the power supply is configured to selectively vary or control the WCS bias voltage. As such, the controller 126 can control the WCS bias power supply 122 to tune or match WCS bias voltage 128 in relation to an electrical potential of the workpiece 108, thereby providing an electrostatically repulsive force on the workpiece to assist in its removal. The electrical potential of the workpiece 108, for example, can be determined by a probe or other measurement apparatus configured to determine the electrical potential of the workpiece.

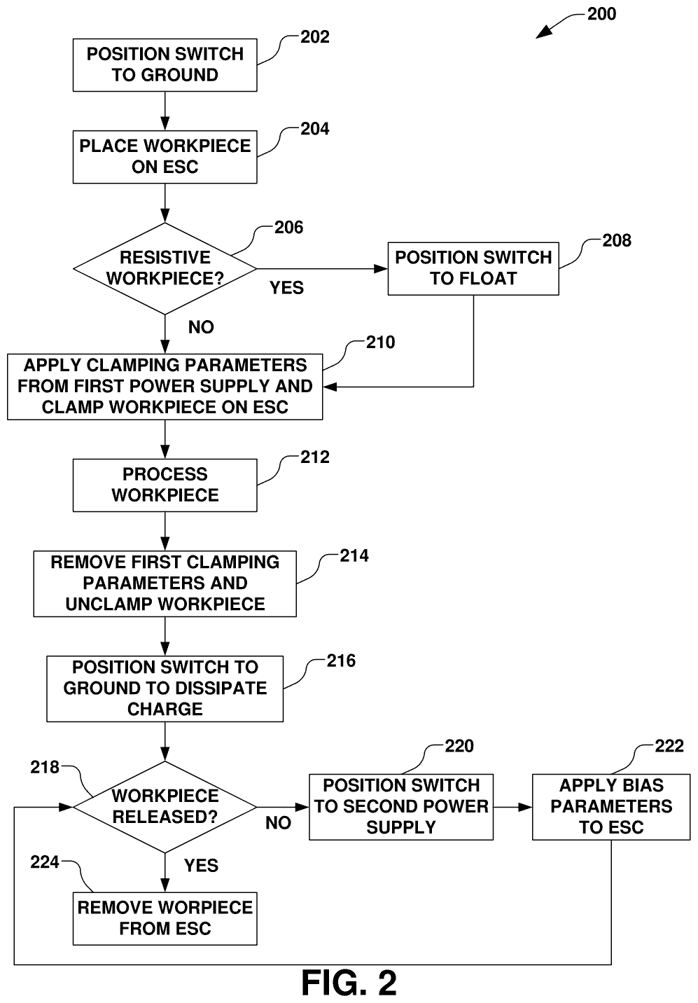

In accordance with another example of the present disclosure, FIG. 2 illustrates a method 200 for clamping and de-clamping a workpiece to and from an ESC. It should be noted that while exemplary methods are illustrated and described herein as a series of acts or events, it will be appreciated that the present invention is not limited by the illustrated ordering of such acts or events, as some steps may occur in different orders and/or concurrently with other steps apart from that shown and described herein, in accordance with the invention. In addition, not all illustrated steps may be required to implement a methodology in accordance with the present invention. Moreover, it will be appreciated that the methods may be implemented in association with the systems illustrated and described herein as well as in association with other systems not illustrated.

The method 200 of FIG. 2 begins at act 202, whereby a clamping surface of an ESC is electrically coupled to an electrical ground, such as via a control of the switch circuit 118 of FIG. 1. In act 204 of FIG. 2, a workpiece is placed on the clamping surface of the ESC. In act 206, a determination is made whether the workpiece is a resistive workpiece, whereby in act 208, the clamping surface of the workpiece is electrically floated if the workpiece is substantially resistive (e.g., greater than a predetermined resistivity). For example, the switch circuit 118 of FIG. 1 can be controlled in act 208 of FIG. 2 to electrically float the clamping surface of the ESC.

The method then proceeds to act 210, whereby a set of clamping parameters are applied to the electrostatic clamp, therein clamping the workpiece to the clamping surface of the electrostatic clamp. For example, a predetermined clamping voltage may be applied to one or more electrodes of the ESC in act 210, whereby the workpiece is electrostatically clamped to the clamping surface with a predetermined clamping force. In act 212, the workpiece is processed, such as via an ion implantation or other semiconductor process. In act 214, the set of clamping parameters applied in act 210 are removed or otherwise halted. In act 216, the clamping surface of the ESC is electrically coupled to the electrical ground, whereby electrical charge that may have built up in the workpiece is permitted to dissipate.

In act 218, a determination is made regarding whether the workpiece is sufficiently released or unclamped from the clamping surface to permit an acceptable removal of the workpiece from the clamping surface, thereby define a released status. If the determination in act 218 is that the workpiece is not sufficiently released, the clamping surface is electrically coupled to a bias power supply in act 220, such as via the switch circuit 118 of FIG. 1 switching the electrical coupling of the WCS electrical contact 116 to the WCS bias power supply 122. Accordingly, in act 222 of FIG. 2, bias parameters are applied to the ESC, such as by providing the WCS bias voltage 128 to the WCS electrical contact 116 of FIG. 1, thereby sufficiently resolving residual electrostatic forces between the clamping surface 104 and the workpiece 108.

After the residual charges are dissipated and it is determined that the workpiece is no longer clamped to the ESC in act 218 of FIG. 2, the workpiece can be safely removed from the clamping surface of the electrostatic clamp in act 224. For example, the monitor 139 of FIG. 1 can be configured to provide feedback associated with the state of clamping or sticking of the workpiece 108 to the clamping surface 104, such that the workpiece can be safely unclamped and removed from the ESC 102.

In one example, the electrostatic clamping and de-clamping of the workpiece with respect to the electrostatic clamp is based on a physical property of the workpiece. The physical property of the workpiece, for example, can comprise one or more of a constituent material of the workpiece, a physical structure of the workpiece, and one or more layers defined on the workpiece.

The control of the switch circuit 118 of FIG. 1 and in acts 202, 208, and 222 of FIG. 2, for example, can comprise selectively electrically coupling the WCS electrical contact 116 of the electrostatic clamp 102 to the electrical ground 120, WCS bias power supply 122, and float position 124 based on a signal to an automated switch. Alternatively, controlling the switch circuit 118 comprises the aforementioned selective electrical coupling via a manual selection of a manual switch by a human operator.

As stated in the above example, the clamping surface 104 of the electrostatic clamp 102, for example, can comprise the one or more surface layers 143 (e.g., one or more charge dissipation layers), wherein control of the switch circuit 118 can comprise electrically coupling the one or more surface layers to the respective electrical ground 120, WCS bias power supply 122, and float position 124. The one or more surface layers 143, for example, can be configured to dissipate a charge associated with one or more of the clamping surface 104 and the workpiece 108 based, at least in part, on the amount of electrical grounding to one or more of the workpiece and the electrostatic clamp 102.

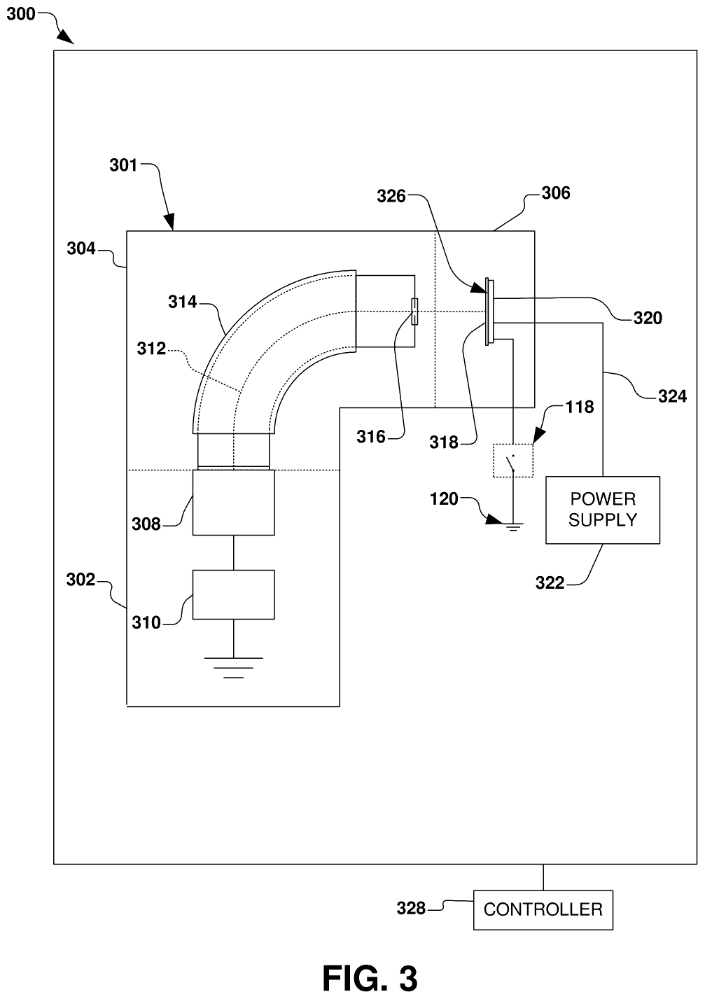

In accordance with yet another aspect of the present disclosure, FIG. 3 illustrates an exemplary vacuum system 300 in which various aspects of the present may be practiced. The vacuum system 300 in the present example comprises an ion implantation system 301, however various other types of vacuum systems are also contemplated, such as plasma processing systems, or other semiconductor processing systems. The ion implantation system 301, for example, comprises a terminal 302, a beamline assembly 304, and an end station 306. Generally speaking, an ion source 308 in the terminal 302 is coupled to a power supply 310 to ionize a dopant gas into a plurality of ions and to form an ion beam 312. The ion beam 312 in the present example is directed through a beam-steering apparatus 314, and out an aperture 316 towards the end station 306. In the end station 306, the ion beam 312 bombards a workpiece 318 (e.g., a semiconductor such as a silicon wafer, a display panel, etc.), which is selectively clamped or mounted to an electrostatic clamp 320 (ESC). Once embedded into the lattice of the workpiece 318, the implanted ions change the physical and/or chemical properties of the workpiece. Because of this, ion implantation is used in semiconductor device fabrication and in metal finishing, as well as various applications in materials science research.

The ESC 320, for example, is electrically coupled to a power supply 322. The ESC 320, for example, may comprise a multiple-phase alternating current (AC) clamp (e.g., a three-phase ESC), whereby the power supply 322 (e.g., a three-phase or six-phase power supply) is configured to provide multiple-phase power to the multiple-phase AC clamp. In other examples, the ESC 320 comprises a direct current (DC) clamp, whereby the power supply 322 is configured to provide DC power to the DC clamp. The power supply 322, for example, is configured to control a current, a voltage, and a frequency of power 324 (e.g., AC or DC power) supplied to the ESC 320, thereby selectively clamping the workpiece 318 to a surface 326 of the ESC. A controller 328, for example, is further provided, wherein the controller is operable to control the power supply 322 and/or various other aspects of the vacuum system 300.

Although the invention has been shown and described with respect to a certain embodiment or embodiments, it should be noted that the above-described embodiments serve only as examples for implementations of some embodiments of the present invention, and the application of the present invention is not restricted to these embodiments. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more other features of the other embodiments as may be desired and advantageous for any given or particular application. Accordingly, the present invention is not to be limited to the above-described embodiments, but is intended to be limited only by the appended claims and equivalents thereof.

1. An electrostatic clamping system comprising:
a clamping power supply configured to supply a clamping voltage;
a bias power supply configured to supply a bias voltage;
an electrostatic clamp comprising:
a clamping surface configured to contact a backside surface of a workpiece;
one or more electrodes positioned below the clamping surface, wherein the clamping power supply is configured to supply the clamping voltage to the one or more electrodes to electrostatically attract the workpiece to the clamping surface; and
an electrical contact electrically coupled to the clamping surface; and
a switch circuit configured to selectively electrically couple the electrical contact to each of an electrical ground, the bias power supply, and an open position based on one or more conditions, wherein the electrical ground is configured to electrically ground the clamping surface, wherein the bias power supply is configured to finitely bias the clamping surface to the bias voltage, and wherein the open position is configured to electrically float the clamping surface.

2. The electrostatic clamping system of claim 1, wherein the one or more conditions comprise a physical property of the workpiece.

3. The electrostatic clamping system of claim 2, wherein the physical property of the workpiece comprises one or more of a constituent material of the workpiece, a physical structure of the workpiece, and one or more layers defined on the workpiece.

4. The electrostatic clamping system of claim 3, wherein the constituent material comprises one or more of silicon, glass, carbide, and nitride.

5. The electrostatic clamping system of claim 3, wherein the one or more layers defined on the workpiece comprise a backside film disposed on the workpiece and defining the backside surface, and wherein the backside film is electrically insulative, electrically conductive, or electrically semi-conductive.

6. The electrostatic clamping system of claim 3, wherein the physical structure of the workpiece comprises one or more features defined on the backside surface of the workpiece.

7. The electrostatic clamping system of claim 1, further comprising a controller configured to control the switch circuit based on the one or more conditions, and wherein the switch circuit further comprises an automated electrical switch configured to selectively electrically couple the electrical contact of the electrostatic clamp to the electrical ground based on a signal from the controller.

8. The electrostatic clamping system of claim 7, wherein the one or more conditions comprise a state of sticking of the workpiece to the clamping surface after semiconductor processing has been performed on the workpiece.

9. The electrostatic clamping system of claim 8, further comprising a monitor configured to provide feedback to the controller from one or more of the clamping power supply and the bias power supply, wherein the feedback is associated with a state of sticking of the workpiece to the clamping surface.

10. The electrostatic clamping system of claim 1, wherein the switch circuit comprises an electrical switch configured to selectively electrically couple the electrical contact of the electrostatic clamp to the electrical ground via a manual selection by a human operator.

11. The electrostatic clamping system of claim 1, wherein the electrical contact comprises a ground pin associated with the clamping surface.

12. The electrostatic clamping system of claim 11, wherein the ground pin is configured to electrically contact the backside surface of the workpiece when the backside surface is in contact with the clamping surface.

13. The electrostatic clamping system of claim 1, wherein the clamping power supply is configured to selectively vary the clamping voltage.

14. The electrostatic clamping system of claim 1, wherein the clamping surface comprises one or more surface layers.

15. The electrostatic clamping system of claim 14, wherein the one or more surface layers are configured to dissipate a charge associated with one or more of the clamping surface and the workpiece based, at least in part, on the selective electrical coupling of the electrical contact to the electrical ground or the bias power supply.

16. A method for clamping a workpiece, the method comprising:
placing the workpiece on a clamping surface of an electrostatic clamp;
electrically grounding or electrically floating the clamping surface of the electrostatic clamp based on one or more predetermined conditions associated with the workpiece and the electrostatic clamp;
applying a set of clamping parameters to the electrostatic clamp, therein clamping the workpiece to the clamping surface of the electrostatic clamp;
processing the workpiece;
selectively electrically coupling the clamping surface to an electrical ground after processing the workpiece;
determining a release status of the workpiece, wherein the release status comprises one of a clamped state or a released state, wherein the workpiece is clamped to the clamping surface in the clamped state, and wherein the workpiece is released from the clamping surface in the released state;
applying a bias potential to the clamping surface when the release status of the workpiece is in the clamped state;
and
removing the workpiece from the clamping surface when the workpiece is in the released state.

17. The method of claim 16, further comprising dissipating residual charge from the electrostatic clamp prior to removing the workpiece from the clamping surface.

18. The method of claim 16, wherein the one or more predetermined conditions comprise a physical property of the workpiece, wherein the physical property of the workpiece comprises one or more of a constituent material of the workpiece, a physical structure of the workpiece, and one or more layers defined on a backside surface of the workpiece.

19. The method of claim 16, wherein selectively electrically coupling the clamping surface to the electrical ground comprises controlling a switch to selectively electrically couple the clamping surface to the electrical ground.

20. The method of claim 16, wherein the one or more predetermined conditions comprise a resistivity of the workpiece, wherein the clamping surface is electrically floated when the resistivity of the workpiece is greater than a predetermined resistivity.

21. The method of claim 16, wherein applying the set of clamping parameters to the electrostatic clamp comprises supplying a clamping voltage to one or more electrodes of the electrostatic clamp.

22. The method of claim 21, further comprising selectively varying the clamping voltage.

23. The method of claim 20, wherein clamping surface comprises one or more charge dissipation coatings defined thereon, and wherein the one or more charge dissipation coatings are configured to dissipate a charge associated with one or more of the clamping surface and the workpiece based, at least in part, on the selective electrical coupling the clamping surface to the electrical ground.
